(19) United States
(12) Patent Application Publication
(10) Pub. No.: US 2007/0263363 A1
(43) Pub. Date: Nov. 15, 2007

(54) FIXING APPARATUS FOR HEAT SINK

(75) Inventors: JIN-BIAO LIU, Shenzhen (CN); SHIH-HSUN WUNG, Tu-Cheng (TW); GUANG YU, Shenzhen (CN); CHUN-CHI CHEN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Foxconn Technology Co., Ltd., Tu-Cheng (TW)

(21) Appl. No.: 11/561,324

(22) Filed: Nov. 17, 2006

(30) Foreign Application Priority Data
May 12, 2006 (CN) 200610060628.6

(51) Int. Cl. H05K 7/20

(52) U.S. Cl. 361/719

(57) ABSTRACT

A fixing apparatus adapted for attaching a heat sink to a circuit board on which an electronic component is mounted includes a fastener and a back plate. The fastener comprises an elongated pressing part holding the heat sink in contact with the electronic component and two latching legs extending downward from two opposite ends of the pressing part. The latching legs each have at least one hook extending inward from a distal end thereof. The back plate comprises a main body and a plurality of connecting members at two opposite ends of the main body for extending upwardly through the circuit board to engage with the hooks of the fastener.

### BACKGROUND OF THE INVENTION

1. Field of the Invention

The present invention relates generally to a fixing apparatus, and more particularly to a fixing apparatus for securing a heat sink to an electronic component to remove heat from the electronic component.

2. Description of Related Art

Heat sinks are usually used to remove heat from electronic components, such as central processing units (CPUs) and the like, to keep the components at specified temperatures. A typical heat sink comprises a base for contacting an electronic component to absorb the heat originating from the electronic component and a plurality of fins extending from the base for dissipating the heat to ambient air.

To conveniently secure the heat sink to the electronic component, a retention module is required to be mounted on the motherboard for supporting the heat sink thereon. A back plate is employed beneath the motherboard to reinforce the motherboard.

U.S. Pat. No. 6,549,412 B1 illustrates an example of applying a retention module and a back plate to secure a heat sink. The motherboard defines a plurality of through apertures therein. The retention module includes a plurality of posts extending downwardly therefrom. Each post defines a though hole in alignment with a corresponding through aperture. The back plate includes a plurality of upwardly extending poles. The poles extend through the through holes and the through apertures and protrude from the retention module. Top ends of the poles are stamped downward forming rivet joints connecting the retention module, the motherboard and the back plate together.

However, the stamping operation is awkward when used to secure the retention module and the back plate, and puts the motherboard at the risk of being damaged. Additionally, to secure the heat sink to the electronic component, a clip for engaging with the retention module is required.

What is needed is a fixing apparatus which can easily and firmly attach a heat sink to an electronic component.

### SUMMARY OF THE INVENTION

A fixing apparatus accordance with a preferred embodiment of the present invention includes a fastener and a back plate. The fastener comprises an elongated pressing part adapted for holding a heat sink in contact with an electronic component and two latching legs extending downward from two opposite ends of the pressing part. Each latching leg includes at least one hook extending inward from a distal end thereof. The back plate comprises a main body and a plurality of connecting members at two opposite ends of the main body for extending upwardly through the circuit board to engage with the hooks of the fastener.

Other advantages and novel features will become more apparent from the following detailed description of preferred embodiments when taken in conjunction with the accompanying drawings, in which:

### BRIEF DESCRIPTION OF THE DRAWINGS

The fixing apparatus can be better understood with reference to many aspects of the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is an exploded, isometric view of a fixing apparatus in accordance with a preferred embodiment of the present invention, together with a heat sink and a circuit board having an electronic component mounted thereon;

FIG. 2 is an assembled view of FIG. 1;

FIG. 3 is a side elevation of FIG. 2;

FIG. 4 is an exploded, isometric view of a fixing apparatus in accordance with an alternative embodiment of the present invention, together with a heat sink and a circuit board having an electronic component mounted thereon;

FIG. 5 is an assembled view of FIG. 4; and

FIG. 6 is a side elevation of FIG. 4.

### DETAILED DESCRIPTION OF THE INVENTION

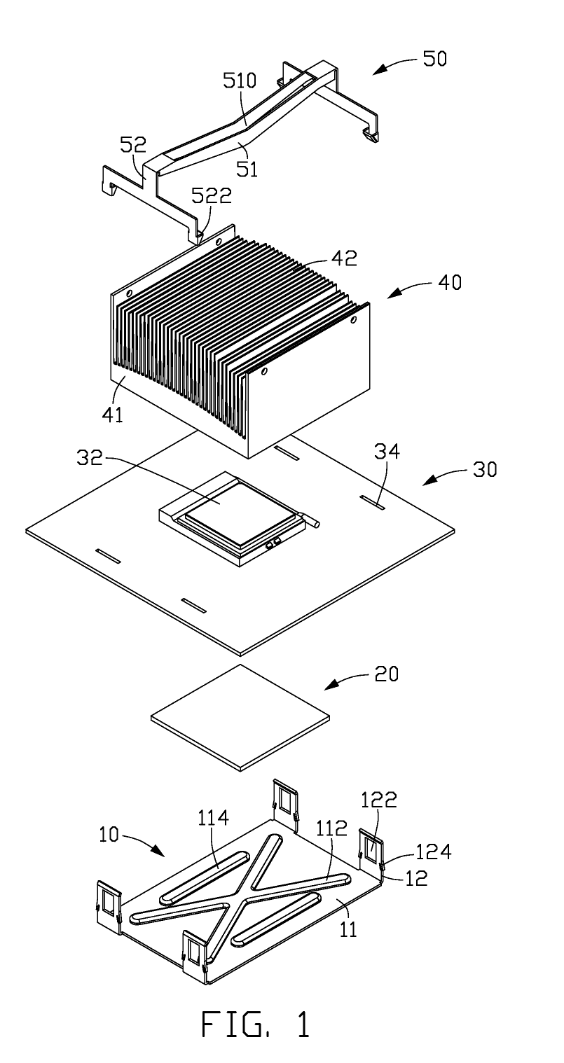

Referring to FIGS. 1-3, a fixing apparatus in accordance with a preferred embodiment of the present invention is for attaching a heat sink 40 to an electronic component 32 mounted on a circuit board 30 via a socket (not labeled). The fixing apparatus comprises a back plate 1 0 and a fastener 50. The fastener 50 spans the heat sink 40 and engages with the back plate 10. An insulating tape 20 is sandwiched between the back plate 10 and the circuit board 30 to electrically isolate them from each other.

The circuit board 30 defines four through slots 34 therein. The slots 34 are located symmetrically around the electronic component 32. The slots 34 are elongated and parallel to each other. The heat sink 40 comprises a base 41 for contacting with a top surface of the electronic component 32 and a plurality of fins 42 extending upwardly from the base 41. The fins 42 are parallel to and separate from each other.

As illustrated in FIG. 1, the back plate 10 in the first preferred embodiment is integrally formed from a sheet of metal, such as stainless steel. The back plate 10 has a rectangular main body 11 and two pairs of spaced latching flakes 12 serving as a connecting member for holding the back plate 10 in position and engaging with the fastener 50. The latching flakes 12 extend upwardly from two opposite lateral sides of the main body 11 and each defines a first portion, a second portion and a third portion between the first and second portions. The first portion is located at a top of the latching flake 12 and defines an opening 1 22 therein for engaging with the fastener 50. The third portion at a middle of the latching flake 12, has a barb 124 projecting outwardly from each lateral side thereof for locking the back plate 10 in place beneath the circuit board 30 after the barbs 124 of the latching flakes 12 pass through the slots 34 of the circuit board 30. The main body 11 has an X-shaped rib 112 and a pair of straight ribs 114 protruding from a top surface thereof for reinforcing the main body 11.

The fastener 50 has an elongated pressing part 51, which is substantially V-shaped for holding the heat sink 40 in contact with the electronic component 32, and defines a channel 510 between two opposite ends thereof for the central fins 42 extending through. Two latching legs 52 are bent downwardly and perpendicularly from two opposite ends of the pressing part 51. The latching leg 52 is inverted T-shaped. Two spaced hooks 522 are formed at two opposite distal ends of the latching legs 52. The hooks 522 extend inwardly for engaging in their respective openings 122 in the latching flakes 12 of the back plate 10.

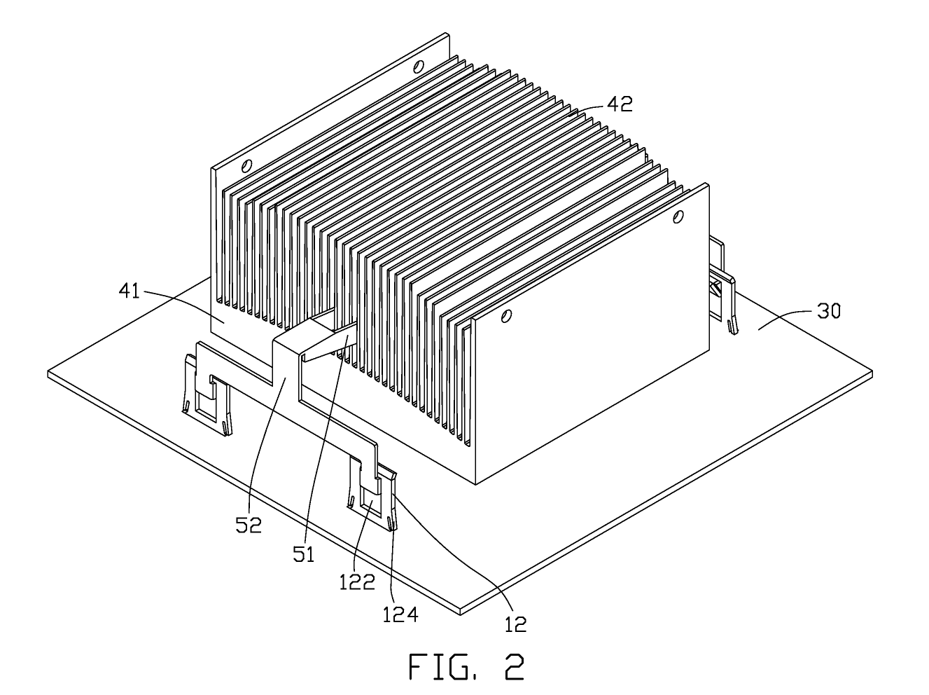

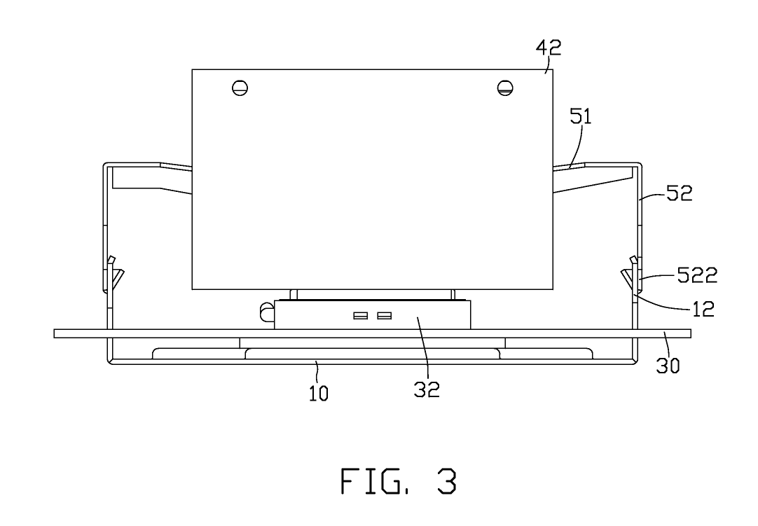

Referring to FIGS. 2 and 3, during use of the fixing apparatus, the insulating tape 20 is placed on the ribs 112 and 114 of the back plate 10. The latching flakes 12 of the back plate 10 are then extended through the corresponding slots 34 of the circuit board 30 until the barbs 124 of the latching flakes 12 upwardly pass through the circuit board 30. The barbs 124 are deformed when they are pressed inwards by the circuit board 30, thus allowing the latching flakes 12 to pass through the slots 34. After the barbs 124 travel to a level above the circuit board 30, they subsequently return to their initial positions and are held by the circuit board 30. The back plate 10 is thus fixed beneath the circuit board 30 by the barbs 124 of the latching flakes 12 in engagement with the circuit board 30. At this time, the openings 122 located in the first portion of the latching flakes 12 are disposed above the circuit board 30. The heat sink is then disposed on the circuit board 30 and is in contact with the electronic component 32. The fastener 50 spans the heat sink 40 with the central fins 42 of the heat sink 40 extending through the channel 510. Finally, two opposing ends of the pressing part 51 of the fastener 50 are pressed downwardly to engagingly receive the hooks 522 of the latching legs 52 in the openings 122 of the latching flakes 12. At this time, the pressing part 51 of the fastener 50 is kept in a state of elastic deformation against the base 41 of the heat sink 40, urging the heat sink 40 downward to closely contact with the electronic component 32.

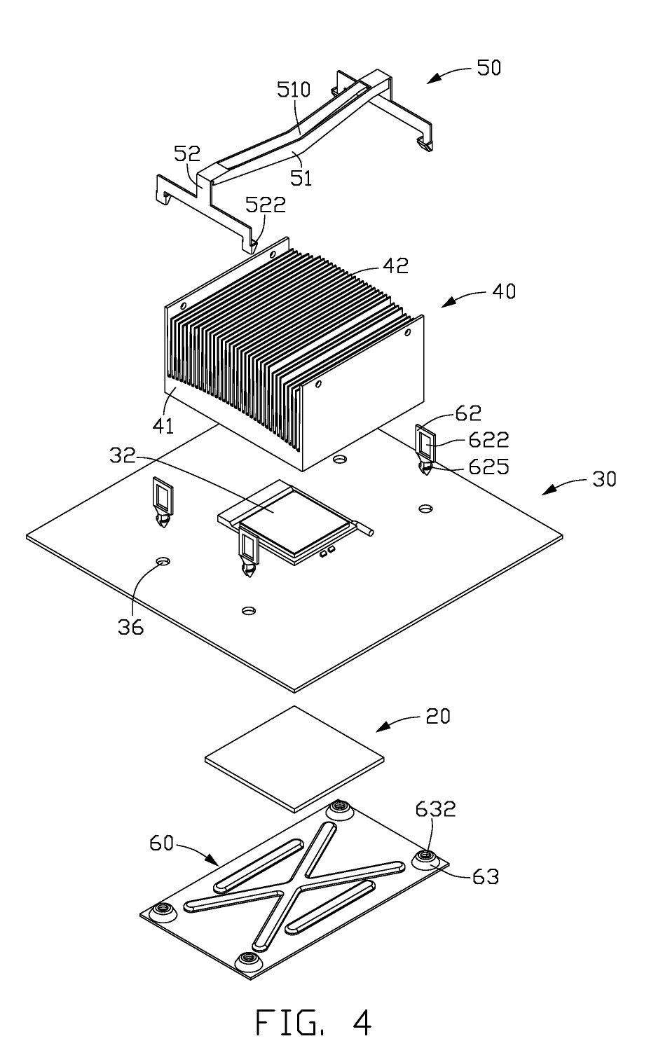

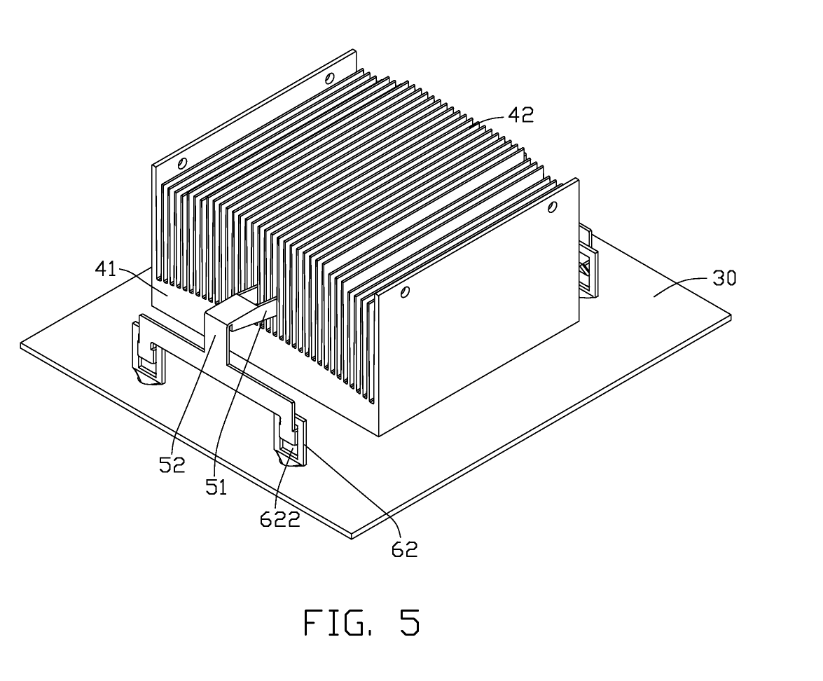

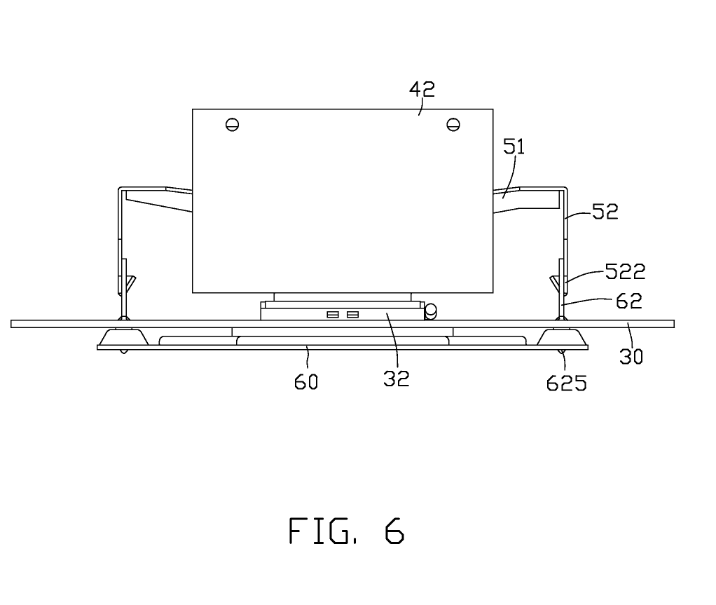

FIGS. 4-6 show another fixing apparatus similar to that of the first preferred embodiment. However, four locking members 62 serving as the connecting member are applied to position a back plate 60 to a circuit board 30. Each locking member 62 comprises a first portion at a top thereof for engaging with the fastener, a second portion at a bottom thereof for connecting to the back plate 60 and a third portion between the first and second portions. The circuit board 30 defines four circular through holes 36 symmetrically around the electronic component 32. The back plate 60 has a circular platform 63 upwardly protruding therefrom at each corner thereof. Each platform 63 defines a locking hole 632 at a top thereof. Each locking member 62 is detachably engaged with the back plate 60, and defines an opening 622 at the first portion thereof to engage with the hooks 522 of the fastener 50 to secure the heat sink 40 to the circuit board 30. A prong 625 is formed at the second portion of each locking member 62. After the prongs 625 of the locking members 62 pass through the through holes 36 of the circuit board 30 and deformably engage in the locking holes 632, the first and third portions of the locking member 62 are held above the circuit board 30 and the back plate 60 is thus firmly secured beneath the circuit board 30. Finally, the fastener 50 can securely mount the heat sink 40 to the electronic component 32 by extending the pressing part 51 of the fastener 50 into the fins 42 and fitting the hooks 522 of the fastener 50 into the openings 622 of the locking members 62.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A fixing apparatus adapted for attaching a heat sink to a circuit board on which an electronic component is mounted comprising:
a fastener comprising an elongated pressing part adapted for holding the heat sink in contact with the electronic component and two latching legs extending downward from two opposite ends of the pressing part, the latching legs each comprising at least one hook extending inward from a distal end thereof; and
a back plate comprising a main body and a plurality of connecting members at two opposite ends of the main body adapted for extending upwardly through the circuit board to engage with the hooks of the fastener.

2. The fixing apparatus as claimed in claim 1, wherein the connecting members each have has a barb projecting outwardly from a lateral side thereof.

3. The fixing apparatus as claimed in claim 2, wherein the connecting members each extend integrally from an edge of the main body in a direction perpendicular to the main body.

4. The fixing apparatus as claimed in claim 1, wherein the connecting members connected to the main body are detachable from the main body.

5. The fixing apparatus as claimed in claim 4, wherein the connecting members each define a prong at a bottom thereof, and the main body defines a set of locking holes for engaging with the prongs.

6. The fixing apparatus as claimed in claim 5, wherein the main body is rectangular and defines a circular platform at each corner thereof, and the locking hole is disposed within the platform.

7. The fixing apparatus as claimed in claim 1, wherein the connecting members each define an opening at a top thereof for receiving the at least one hook therein.

8. A combination comprising:
a circuit board having an electronic component mounted on a top surface thereof;
a heat sink disposed above the circuit board and contacting with the electronic component;
a fastener comprising a pressing part pressing the heat sink toward the electronic component and two latching legs bent from two opposite ends of the pressing part;
a back plate disposed below the circuit board; and
a connecting member inserted into the circuit board, the connecting member comprising a first portion engaging with the latching legs to pull the latching legs toward the circuit board, a second portion engaging with the back plate and a third portion positioned between the first and second portions, the third portion being held on the top surface of the circuit board to secure the back plate to the circuit board.

9. The heat dissipation assembly as claimed in claim 8, wherein the connecting member has a barb projecting outwardly from a lateral side of the third portion.

10. The heat dissipation assembly as claimed in claim 9, wherein the connecting member extends integrally from an edge of the main body in a direction perpendicular to the main body.

11. The heat dissipation assembly as claimed in claim 8, wherein the connecting member connected to the main body is detachable from the main body.

12. The heat dissipation assembly as claimed in claim 11, wherein the connecting member defines a prong in the second section, and the main body defines a locking hole to engage with the prong.

13. The heat dissipation assembly as claimed in claim 12, wherein the main body is substantially rectangular and defines a circular platform at a corner thereof, the locking hole is disposed within the platform.

14. The heat dissipation assembly as claimed in claim 8, wherein the connecting member defines an opening in the first portion thereof for receiving the hook therein.
